(19) United States
(12) Patent Application Publication
(10) Pub. No.: US 2003/0085743 A1
(43) Pub. Date: May 8, 2003

(54) Phase locked loop circuit

(76) Inventors: Igor Ullmann, Dresden (DE); Jeannette Kroedel, Dresden (DE); Frank Barth, Radebeul (DE)

Correspondence Address: B. Noel Kivlin, Conley, Rose, & Tayon, P.C., P.O. Box 398, Austin, TX, 78767, US

(21) Appl. No.: 10/185,147

(22) Filed: Jun. 27, 2002

(30) Foreign Application Priority Data
Nov. 8, 2001 (DE) 101 54 993.8

(51) Int. Cl. H03L 7/06

(52) U.S. Cl. 327/156

(57) ABSTRACT

A PLL circuit is provided that comprises a frequency divider that generates a divided frequency signal and a phase frequency detector that receives the divided frequency signal and a reference frequency signal and that is arranged for outputting a first signal for increasing the frequency of an output signal and a second signal for decreasing the frequency of the output signal. Further, there is provided a signal modification unit that receives the first and second signals and that comprises a pulse selector selecting a signal pulse in one of the first and second signals, and a pulse generator for generating a signal pulse simultaneously with the selected signal pulse and adding the generated signal pulse to the other one of the first and second signals.

### BACKGROUND OF THE INVENTION

1. Field of the Invention

The invention generally relates to phase locked loop (PLL) circuits, and in particular to PLL circuits comprising a phase frequency detector that outputs an UP and a DOWN signal.

2. Description of the Related Art

Phase locked loops are widely used in radio, wireless and telecommunications technology for the purpose of frequency synthesis, clock generation, clock recovery, demodulation and others in digital as well as in analog based circuits. In frequency synthesis techniques, phase locked loops represent the dominant method in the wireless communication industry. Current PLL integrated circuits are able to execute all PLL functions on a single, highly integrated digital and mixed signal circuit that operates on low supply voltages and consume very low power. These integrated circuits require only an external frequency reference, voltage control oscillators and a few external passive components to generate the wide range of frequency needed in communications transceivers.

As the number of users has significantly increased in the last few years in cellular telephony and wireless data networks, both interference and signal-to-noise ratio have become important points to be considered in system design. Phase noise and spurious emissions contribute significantly to signal interference and signal-to-noise ratio and are largely dependent on the performance of the PLL. Thus, minimizing phase noise and spurious emissions of the frequency synthesizer is one of the problems of present technologies which are intensely addressed.

Phase locked loops are negative feedback architectures that allow economic multiplication of crystal frequencies by large variable numbers. Thus, the main functionality of PLLs is often to provide an output frequency fₒᵤₜ which is a multiple of the input or reference frequency f_{ref}:

Fₒᵤₜ=M·f_{ref}

where M is an integer within integer-N PLLs or a fractional number in fractional-N PLLs.

The main drawback of integer PLL circuits is based on the fact that the integer number with which the reference frequency is multiplied influences both the channel spacing and the signal phase noise. The minimum channel spacing is the frequency difference of neighboring channels, that is the difference between M·f_{ref} and (M+1)·f_{ref}. This difference is identical to the reference frequency f_{ref}=fₒᵤₜ/M. Thus, for reducing the channel spacing, that is increasing the frequency resolution, the value of M needs to be increased.

On the other hand, an unavoidable fact in digital PLL synthesis circuits is that frequency multiplication by M raises the signal phase noise by 20 log (M) [dB]. Thus, for decreasing phase noise the value of M should be reduced.

To overcome the restrictions imposed by the mentioned constraints to M, fractional-N PLLs have been developed that theoretically can realize any ratio of fₒᵤₜ/f_{ref}. This is accomplished by adding internal circuitry that enables the value of M to change dynamically during the locked state. This scheme thus allows for using a reference frequency f_{ref} that is greater than the channel spacing.

An example of a conventional fractional-N PLL frequency synthesizer is depicted in FIG. 1. As can be seen from the figure, the PLL frequency synthesizer has a forward signal path that includes a phase frequency detector 100, a charge pump 110, a loop filter 120 and a voltage controlled oscillator 130, and a feedback path that includes a fractional division unit 140, i.e. an accumulator, prescaler, etc. The fractional division unit 140 receives the output signal of the synthesizer and divides the output frequency fₒᵤₜ by the fractional number. The divided frequency signal f_{div} is then supplied to the phase frequency detector 100.

As mentioned above, dividing the output frequency by a fractional number is done by changing the fractional division unit 140 in the loop dynamically, between the values N and N+1 in such a way that the average division becomes a fraction N+K/F. For this purpose, the fractional division unit 140 receives a signal MOD for switching the fractional divisional unit 140 between N and N+1. As the output frequency becomes

fₒᵤₜ=f_{ref}·(N+K/F),

F is the fractional modulus of the synthesizer with respect to the reference frequency. Thus, division is done K times by N+1 and F−K times by N. The principle of fractionality is therefore a result of averaging.

As shown in FIG. 1, the divided frequency signal f_{div} and the reference frequency f_{ref} are supplied to the phase frequency detector 100. The detector 100 generates the error signal required in the feedback loop of the synthesizer. The term “phase frequency detector” is used for indicating that the detector can operate in the phase locked mode where the frequency signal and the divided frequency signal have essentially the same frequency but may differ in their phase, as well as in the mode before the PLL has locked, that is where the reference frequency and the divided frequency differ by more than just a phase error.

The phase frequency detector 100 outputs an UP and DOWN signal to the charge pump 110. The UP signal is output when the phase frequency detector 100 detects that there is a frequency of phase difference between f_{ref} and f_{div} of such a kind that the output frequency fₒᵤₜ needs to be increased. On the other hand, the DOWN signal is output when the output frequency needs to be decreased.

An example of a phase frequency detector 100 and a charge pump 110 in the conventional PLL frequency synthesizer is depicted in FIG. 2. In this example, the phase frequency detector 100 comprises two D flip-flops 120, 130 that are set at the rising edges of the f_{ref} and f_{div} signals, respectively. The UP and DOWN signals represent the values stored in the respective flip-flops. When both signals are high, the flip-flops are cleared by an extra circuitry provided in the detector 100.

The operation of the phase frequency detector 100 shown in FIG. 2 can be better understood from studying the waveforms that are depicted in FIG. 3. In FIG. 3, the PLL frequency synthesizer operates in the phase detect mode since there is a phase difference, or “phase error”, between the reference frequency signal and the divided frequency signal. When the reference frequency signal increases while the divided frequency signal is low, the flip-flop 120 is set. Thus, the UP signal increases from low to high. After a time that corresponds to the phase difference, the divided frequency signal increases, thereby setting the flip-flop 130. As a consequence, the DOWN signal raises, and since the UP and the DOWN signal are both high, the flip-flops are cleared. Therefore, the UP signal goes down.

That is, the phase frequency detector 100 compares the reference frequency signal with the divided frequency signal and activates the charge pump 110 based on the difference in phase of frequency between these two signals. The charge pump receives the UP and DOWN signals and creates a tuning voltage that is provided to the loop filter 120. As can be seen from FIG. 3, since in the depicted example there is a sequence of UP signals provided to the charge pump, the tuning voltage (i.e. loop filter charge) increases step by step.

The loop filter 120 is used to prevent unwanted spurious noise generated by the phase frequency detector 100. Since the detector 100 generates high levels of transient noise at its frequency of operation, that is at the reference frequency f_{ref}, there is noise superimposed on the voltage used for controlling the voltage controlled oscillator 130. The voltage controlled oscillator 130 generates a frequency that depends on the input control voltage, and whenever this control voltage has noise superimposed, the oscillator output is modulated accordingly. This interference can be seen as spurious signals and is filtered by loop filter 120.

While the conventional fractional-N PLL systems have numerous advantages over integer-N PLLs, in particular the capability of realizing any ratio of fₒᵤₜ/f_{ref}, higher loop filter bandwidth, better phase noise rejection and a better loop settling behavior, a problem still arises from the fact that the fractional PLL system generates spurious signals at the output.

Several techniques have been developed for compensating such spurious signals generated by the fractional division unit 140 and the phase frequency detector 100. These techniques include additional charge injection to the loop filter that is proportional to the phase error at the phase frequency detector, by means of a compensation charge pump. The implementation of such compensation circuitry is however rather complex as it usually involves digital to analog conversion and extra charge compensation. Such techniques suffer from the non-ideal component behavior, from temperature and long term influences and from the need to be calibrated for best performance.

### SUMMARY OF THE INVENTION

A PLL circuit is disclosed that may provide improved spurious signal rejection.

In one embodiment, a phase locked loop circuit comprises a frequency divider that receives the output of the circuit and that generates a divided frequency signal therefrom by dividing the frequency of the output signal. The PLL circuit further comprises a phase frequency detector that receives the divided frequency signal and a reference frequency signal. The phase frequency detector is arranged for outputting a first signal for increasing the frequency of the output signal and a second signal for decreasing the frequency of the output signal, in response to a frequency of phase difference between the divided frequency signal and the reference frequency signal. The first and second signals include signal pulses. The PLL circuit further comprises a signal modification unit that receives the first and second signals and that comprises a pulse selector for selecting a signal pulse in one of the first and second signals, and a pulse generator for generating a signal pulse simultaneously with the selective signal pulse and adding the generated signal pulse to the other one of the first and the second signals.

In a further embodiment, a fractional-N PLL circuit is provided that comprises a frequency divider that receives the output signal of the circuit and generates a divided frequency signal therefrom by dividing the frequency of the output signal by a fractional number. The fractional-N PLL circuit further comprises a voltage controlled oscillator for generating the output signal at a frequency that depends on a control voltage supplied to the voltage controlled oscillator. Further, the fractional-N PLL circuit comprises a phase frequency detector receiving the divided frequency signal and a reference frequency signal. The phase frequency detector is arranged for outputting a first signal for increasing the frequency of the output signal and a second signal for decreasing the frequency of the output signal, in response to a frequency or phase difference between the divided frequency signal and the reference frequency signal. The first and second signals include signal pulses. The fractional-N PLL circuit further comprises a signal modification unit that receives the first and second signals and that comprises a pulse selector for selecting a signal pulse in one of the first and second signals, and a pulse generator for generating a signal pulse simultaneously with the selected signal pulse and adding the generated signal pulse to the other one of the first and second signals. Furthermore, the fractional-N PLL circuit comprises a charge pump connected to the signal modification unit for receiving the modified first and second signals therefrom that include the selected and generated signal pulse, respectively, and for generating a tuning voltage used for controlling the voltage controlled oscillator.

### BRIEF DESCRIPTION OF THE DRAWINGS

The accompanying drawings are incorporated into and form a part of the specification to illustrate several embodiments of the present invention. These drawings together with the description serve to explain the principles of the invention. The drawings are only for the purpose of illustrating alternative examples of how the invention can be made and used and are not to be construed as limiting the invention to only the illustrated and described embodiments. Further features and advantageous will become apparent from the following and more particular description of the various embodiments of the invention, as illustrated in the accompanying drawings, wherein:

FIG. 1 illustrates a conventional fractional-N PLL circuit;

FIG. 2 illustrates the phase frequency detector and the charge pump of the conventional fractional-N PLL circuit shown in FIG. 1;

FIG. 3 is a time chart showing waveforms within a fractional-N PLL circuit in the phase detect mode;

FIG. 4 is a time chart showing waveforms within a fractional-N PLL circuit in the phase locked loop;

FIG. 5 is a fractional-N PLL circuit according to an embodiment of the invention;

FIG. 6 is a time chart illustrating the wave forms of the fractional-N PLL circuit shown in FIG. 5 in the phase locked mode; and

FIG. 7 illustrates the signal modification unit used in the fractional-N PLL circuit shown in FIG. 5.

### DETAILED DESCRIPTION OF THE INVENTION

The illustrative embodiments of the present invention will be described with reference to the figure drawings wherein like elements and structures are indicated by like reference numbers.

Spurious signals may be caused by the abrupt change in phase associated with N being incremented to N+1 on a periodic bases. This spur is called the fractional spur and occurs in distances of

$$\pm n \cdot \frac{{f}_{ref}}{F}$$

from the wanted output frequency, where n=1, 2, 3 . . . Thus, the fractional spur can be located as close as f_{ref}/F away from the carrier, where F is the above described denominator in the characteristic fractional-N PLL formula:

fₒᵤₜ=f_{ref}·(N+K/F).

The time period F/f_{ref} is referred to as fractional period hereafter.

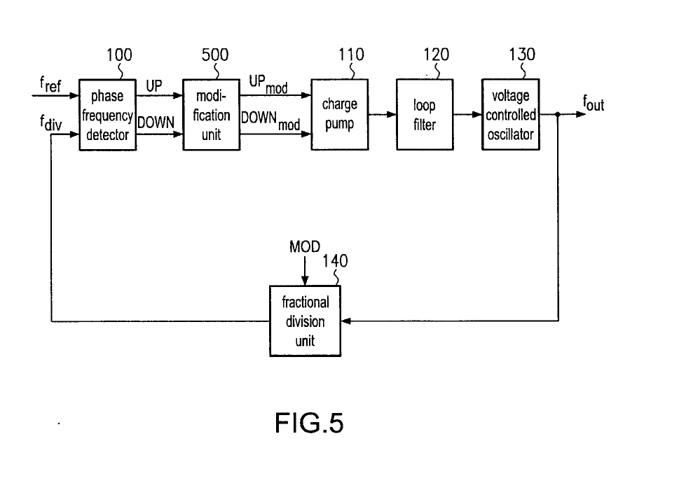

An example of the spurious signal generation is shown in FIG. 4. In this example, the fractional division unit 140 is instructed by means of the MOD signal to switch between modes N and N+1 where N=1, K=3 and F=5. Whenever the MOD signal switches the fractional division unit 140 from mode N to N+1, a spurious DOWN pulse occurs. Similarly, on each transition from mode N+1 to N, a spurious UP pulse is generated.

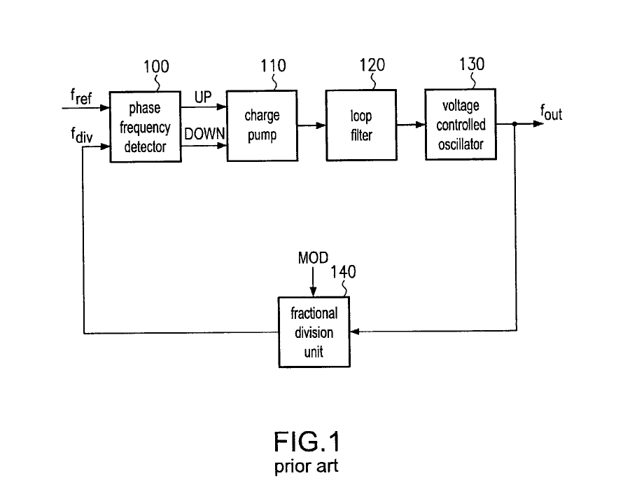

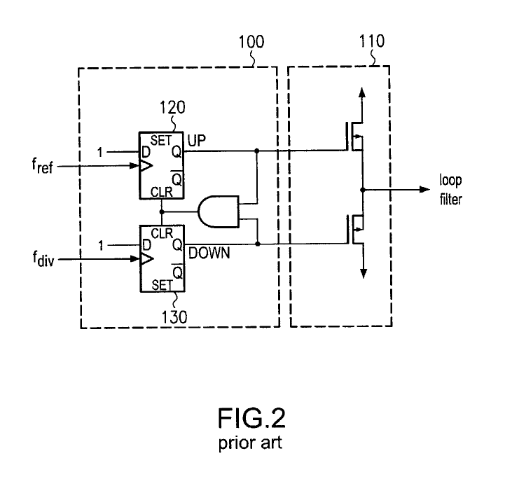

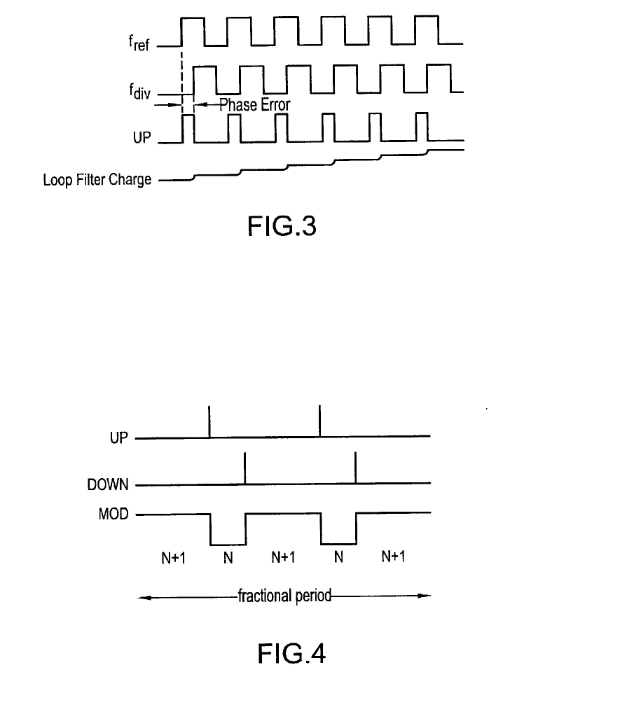

Referring now to FIG. 5 which illustrates one embodiment of a fractional-N PLL circuit, the circuit differs from the conventional PLL circuit shown in FIG. 1 in that there is a signal modification unit 500 provided between the phase frequency detector 100 and the charge pump 110. The signal modification unit 500 receives the UP and DOWN signals from the phase frequency detector 100 and outputs respective modified signals UP_{mod} and DOWN_{mod} to the charge pump 110.

The signal modification unit 500 selects a spurious signal pulse in either the UP or DOWN signals and adds to the other signal a signal pulse that is then output to the charge pump 110 simultaneously. Thus, as there are now UP and DOWN pulses superimposed, an almost entire cancellation of the two pulses is achieved. Only a small spike due to the readjustment of the loop is to be expected. This spike however has a high frequency energy distribution and is therefore well rejected by the voltage control oscillator 130 due to its integrating behavior.

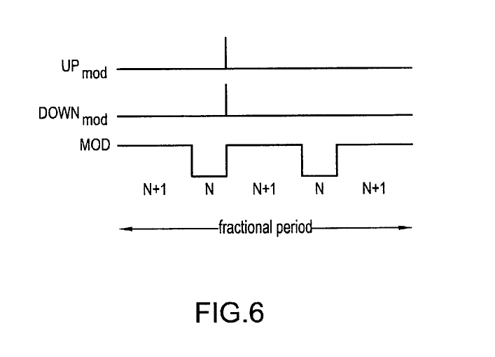

The operation of the signal modification unit 500 will now be described in more detail with reference to FIG. 6 which illustrates the waveforms of the modified UP and DOWN signals. When comparing the UP_{mod} and DOWN_{mod} signals shown in FIG. 6 with the original UP and DOWN signals shown in FIG. 4, it can be seen that in the present embodiment the spurious signal pulses are selected from the DOWN signal. That is, the signal modification unit 500 selects a DOWN pulse and generates (i.e. superimposes) a small UP pulse. In the present embodiment, the other UP pulses coming from the phase frequency detector 100 are filtered out so that the modified signal UP_{mod} include only the generated signal pulse. Further, it can be seen that in the present embodiment all DOWN pulses within the fractional period, with the exception of the selected one, are filtered out. Thus, the signal modification unit 500 outputs in each fractional period only one UP and DOWN pulse, and these pulses are output simultaneously.

When selecting the spurious signal pulse, the fractional-N PLL circuit of the present embodiment uses the widest pulse within one fractional period. That is, when there are more than one DOWN pulses in each fractional period, as this is shown for instance in FIG. 4, the signal modification unit 500 selects the DOWN pulse having the greatest pulse width. The signal pulse generated in the UP_{mod} signal simultaneously with the selected DOWN pulse has in the present embodiment a predetermined pulse width.

The signal modification described above performed by signal modification unit 500 can be performed any time, that is even before the PLL circuit has settled and locked, or it can be switched on after the PLL has settled and locked to the wanted frequency.

A variety of simulations have been performed, including system level simulation using ADS™, PSPICE™ mixed mode and Accusim™ full analog transient simulations for various K, F and N, as well as for different loop filter and voltage controlled oscillator settings, and the simulations have shown that the absolute spurious rejection values are between 60 dB and 70 dB or even beyond, what is about 30 dB better than in the conventional systems.

The embodiment described above may provide a high fractional-N PLL spurious rejection with only little additional circuitry needed and without the requirement of calibrating the circuit. Moreover, the loop characteristics like loop transfer function, natural frequency and loop bandwidth may not be influenced by the embodiment described above.

Moreover, while the embodiment described above may attain improvements with respect to signal-to-noise ratio, reliability, precision, accuracy and efficiency, various embodiments may additionally allow for high spurious signal rejection using a simple circuit design, and thus may allow for reducing the costs of manufacturing.

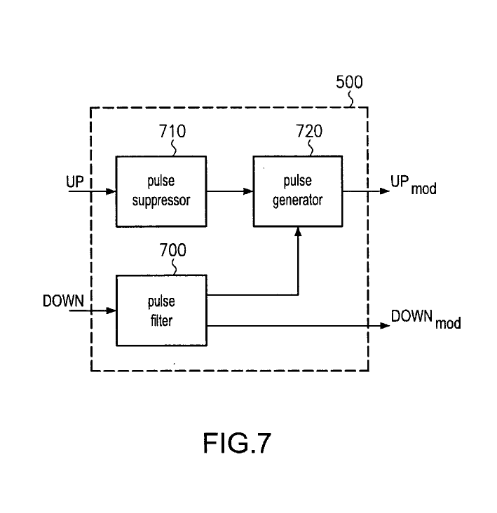

An embodiment of the signal modification unit 500 depicted in FIG. 5 will now be described in more detail with reference to FIG. 7. The signal modification unit 500 comprises a pulse filter 700 that receives the DOWN signal from phase frequency detector 100. The pulse filter 700 filters out the pulse to be selected and forwards either the selected pulse or a corresponding control signal to a pulse generator 720. The selected signal pulse passes through the pulse filter 700 and is provided to the charge pump 110 as the DOWN_{mod} signal.

In the UP signal path, the modification unit 500 includes the pulse generator 720 that generates the simultaneous signal pulse that is provided as UP_{mod} signal to the charge pump. Further, there is comprised a pulse suppressor 710 that receives the UP signal from the phase frequency detector 100 and that suppresses all incoming UP pulses. Any signal that is not suppressed is forwarded to the pulse generator 720 so that the pulse generator 720 can add the generated signal pulse to the UP signal.

While the invention has been described with respect to the physical embodiments constructed in accordance therewith, it will be apparent to those skilled in the art that various modifications, variation and improvements of the present invention may be made in the light of the above teachings and within the purview of the appended claims without departing from the spirit and intended scope of the invention. For instance, while the above embodiment has been described for suppressing spurious signals in fractional-N PLL circuits, it will be appreciated that the principles of the invention can also be applied to integer-N PLL circuits. Moreover, while in the embodiment described above a signal pulse has been generated in the UP_{mod} signal, it is contemplated that a complementary arrangement is likewise possible where the generated signal pulse is superimposed to the DOWN signal.

In addition, those areas in which it is believed that those of ordinary skill in the art are familiar, have not been described herein in order not to unnecessarily obscure the invention described herein. Accordingly, it is to be understood that the invention is not to be limited by the specific illustrative embodiments, but only by the scope of the appended claims.

1. A PLL (phase locked loop) circuit comprising:
a frequency divider receiving the output signal of the circuit and generating a divided frequency signal therefrom by dividing the frequency of the output signal;
a phase frequency detector receiving said divided frequency signal and a reference frequency signal, the phase frequency detector being arranged for outputting a first signal for increasing the frequency of the output signal and a second signal for decreasing the frequency of the output signal, in response to a frequency or phase difference between said divided frequency signal and said reference frequency signal, said first and second signals including signal pulses; and
a signal modification unit receiving the first and second signals, said signal modification unit comprising:
a pulse selector for selecting a signal pulse in one of the first and second signals; and
a pulse generator for generating a signal pulse simultaneously with the selected signal pulse and adding the generated signal pulse to the other one of the first and second signals.

2. The PLL circuit of claim 1, being a fractional-N PLL circuit wherein said frequency divider is arranged for dividing the frequency of the output signal by a fractional number.

3. The PLL circuit of claim 2 wherein said frequency divider is arranged for receiving a mode control signal for controlling the mode of the frequency divider, the frequency divider being controlled by said mode control signal to alternately switch between a first and a second mode having different division factors such that when averaged the divider divides by said fractional number, and wherein said signal pulses included in the first and second signals occur when the frequency divider switches its mode.

4. The PLL circuit of claim 2 wherein said pulse selector is arranged for selecting only one pulse signal in each fractional period.

5. The PLL circuit of claim 4 wherein said pulse selector is arranged for selecting the signal pulse having the greatest pulse width within the fractional period.

6. The PLL circuit of claim 1, wherein said pulse selector is arranged for suppressing each signal pulse in said one of the first and second signals that is not selected.

7. The PLL circuit of claim 1, wherein said signal modification unit further comprises:
a pulse filter for suppressing each signal pulse in said other one of the first and second signals received from said phase frequency detector.

8. The PLL circuit of claim 1, wherein said pulse selector is arranged for selecting a signal pulse in the second signal, and said pulse generator is arranged for adding the generated signal pulse to the first signal.

9. The PLL circuit of claim 1, wherein said pulse generator is arranged for generating a signal pulse of predetermined pulse width simultaneously with the selected signal pulse.

10. The PLL circuit of claim 1 being a digital integrated circuit.

11. The PLL circuit of claim 1 being operable in a mode where the PLL is unlocked.

12. The PLL circuit of claim 1, further comprising:
a voltage controlled oscillator for generating said output signal, the frequency of which depending on a control voltage supplied to the voltage controlled oscillator on the basis of said first and second signals modified by said signal modification unit.

13. The PLL circuit of claim 12, further comprising:
a charge pump connected to said signal modification unit for receiving the modified first and second signals therefrom including the selected signal pulse and the generated signal pulse, respectively, and for generating a tuning voltage used for controlling said voltage controlled oscillator.

14. The PLL circuit of claim 1, being a PLL frequency synthesizer.

15. A fractional-N PLL (phase locked loop) circuit comprising:
a frequency divider receiving the output signal of the circuit and generating a divided frequency signal therefrom by dividing the frequency of the output signal by a fractional number;
a voltage controlled oscillator for generating said output signal, the frequency of which depending on a control voltage supplied to the voltage controlled oscillator;
a phase frequency detector receiving said divided frequency signal and a reference frequency signal, the phase frequency detector being arranged for outputting a first signal for increasing the frequency of the output signal and a second signal for decreasing the frequency of the output signal, in response to a frequency or phase difference between said divided frequency signal and said reference frequency signal, said first and second signals including signal pulses;
a signal modification unit receiving the first and second signals, said signal modification unit comprising a pulse selector for selecting a signal pulse in one of the first and second signals, and a pulse generator for generating a signal pulse simultaneously with the selected signal pulse and adding the generated signal pulse to the other one of the first and second signals; and
a charge pump connected to said signal modification unit for receiving the modified first and second signals therefrom including the selected signal pulse and the generated signal pulse, respectively, and for generating a tuning voltage used for controlling the voltage controlled oscillator.

16. The fractional-N PLL circuit of claim 15 wherein said frequency divider is arranged for receiving a mode control signal for controlling the mode of the frequency divider, the frequency divider being controlled by said mode control signal to alternately switch between a first and a second mode having different division factors such that when averaged the divider divides by said fractional number, and wherein said signal pulses included in the first and second signals occur when the frequency divider switches its mode.

17. The fractional-N PLL circuit of claim 15 wherein said pulse selector is arranged for selecting only one pulse signal in each fractional period.

18. The fractional-N PLL circuit of claim 17 wherein said pulse selector is arranged for selecting the signal pulse having the greatest pulse width within the fractional period.

19. The fractional-N PLL circuit of claim 15, wherein said pulse selector is arranged for suppressing each signal pulse in said one of the first and second signals that is not selected.

20. The fractional-N PLL circuit of claim 15, wherein said signal modification unit further comprises:
a pulse filter for suppressing each signal pulse in said other one of the first and second signals received from said phase frequency detector.

21. The fractional-N PLL circuit of claim 15, wherein said pulse selector is arranged for selecting a signal pulse in the second signal, and said pulse generator is arranged for adding the generated signal pulse to the first signal.

22. The fractional-N PLL circuit of claim 15, wherein said pulse generator is arranged for generating a signal pulse of predetermined pulse width simultaneously with the selected signal pulse.

23. The fractional-N PLL circuit of claim 15 being a digital integrated circuit.

24. The fractional-N PLL circuit of claim 15 being operable in a mode where the PLL is unlocked.

25. The fractional-N PLL circuit of claim 15, being a PLL frequency synthesizer.

26. A method of operating a phase locked loop, the method comprising the steps of:
receiving the output signal of the phase locked loop;
dividing the frequency of the output signal thereby generating a divided frequency signal;
receiving a reference frequency signal;
outputting a first signal for increasing the frequency of the output signal and a second signal for decreasing the frequency of the output signal, in response to a frequency or phase difference between said divided frequency signal and said reference frequency signal, said first and second signals including signal pulses;
selecting a signal pulse in one of the first and second signals;
generating a signal pulse simultaneously with the selected signal pulse; and
adding the generated signal pulse to the other one of the first and second signals.

27. The method of claim 26, wherein said step of dividing the frequency is arranged for dividing the frequency of the output signal by a fractional number.

28. The method of claim 27 wherein said step of dividing the frequency comprises the steps of:
receiving a mode control signal for controlling a frequency division mode to alternately switch between a first and a second mode having different division factors such that when averaged, division is performed by said fractional number;
wherein said signal pulses included in the first and second signals occur when the mode is switched.

29. The method of claim 27 wherein said step of selecting a signal pulse is arranged for selecting only one pulse signal in each fractional period.

30. The method of claim 29 wherein said step of selecting a signal pulse is arranged for selecting the signal pulse having the greatest pulse width within the fractional period.

31. The method of claim 26, wherein said step of selecting a signal pulse comprises the step of:
suppressing each signal pulse in said one of the first and second signals that is not selected.

32. The method of claim 26, further comprising the step of:
suppressing each signal pulse in said other one of the first and second signals.

33. The method of claim 26, wherein said step of selecting a signal pulse is arranged for selecting a signal pulse in the second signal, and said step of generating a signal pulse comprises adding the generated signal pulse to the first signal.

34. The method of claim 26, wherein said step of generating a signal pulse is arranged for generating a signal pulse of predetermined pulse width simultaneously with the selected signal pulse.

35. The method of claim 26, arranged for operating a digital integrated circuit.

36. The method of claim 26, further comprising the step of:
switching to a mode where the phase locked loop is unlocked.

37. The method of claim 26, further comprising the steps of:
generating a control voltage on the basis of said first and second signals including the selected signal pulse and the generated signal pulse, respectively; and
generating said output signal, the frequency of which depending on said control voltage.

38. The method of claim 26, arranged for operating a PLL frequency synthesizer.
